(19) United States
(12) Patent Application Publication
(10) Pub. No.: US 2024/0313066 A1
(43) Pub. Date: Sep. 19, 2024

(54) METHOD OF FABRICATING SEMICONDUCTOR DEVICE

(71) Applicant: Samsung Electronics Co., Ltd., Suwon-si (KR)

(72) Inventors: Soo Kyung KIM, Suwon-si (KR); Chan HWANG, Suwon-si (KR); Jonghyun JUNG, Suwon-si (KR); Moosong LEE, Suwon-si (KR)

(73) Assignee: Samsung Electronics Co., Ltd., Suwon-si (KR)

(21) Appl. No.: 18/409,031

(22) Filed: Jan. 10, 2024

(30) Foreign Application Priority Data
Mar. 14, 2023 (KR) 10-2023-0033320

(51) Int. Cl. H01L 29/40; G03F 7/00; G03F 7/20; H01L 21/033; H01L 21/311; H01L 21/3213

(52) U.S. Cl. CPC H01L 29/401; H01L 21/0332; H01L 21/31144; H01L 21/32139; G03F 7/2004; G03F 7/2022; G03F 7/7045

(57) ABSTRACT

A method of fabricating a semiconductor device may include providing a substrate including cell and peripheral regions, forming a cell gate structure on the cell region, forming a peripheral gate structure on the peripheral region, forming a bit line structure on the cell region, forming a preliminary conductive layer to cover the bit line structure and the peripheral gate structure, and etching the preliminary conductive layer to form a landing pad and peripheral conductive pads. The etching of the preliminary conductive layer may include forming lower and photoresist layers on the preliminary conductive layer, performing a first exposure process on the photoresist layer, performing a second exposure process on the photoresist layer, and etching the preliminary conductive layer using the photoresist and lower layers as an etch mask. The first exposure process may expose a portion of the photoresist layer that is on the cell region to light.

### CROSS-REFERENCE TO RELATED APPLICATIONS

This U.S. non-provisional patent application claims priority under 35 U.S.C. § 119 to Korean Patent Application No. 10-2023-0033320, filed on Mar. 14, 2023, in the Korean Intellectual Property Office, the entire contents of which are hereby incorporated by reference.

### BACKGROUND

The present disclosure relates to methods of fabricating a semiconductor device, and in particular, to methods of improving efficiency and productivity in a process of fabricating a semiconductor device.

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also required to have high operating speeds and/or low operating voltages, and in order to satisfy this requirement, it is necessary to increase an integration density of the semiconductor device. However, as the integration density of the semiconductor device increases, the semiconductor device may suffer from deterioration in electrical characteristics and production yield. Accordingly, many studies are being conducted to improve the electrical characteristics and production yield of the semiconductor device.

### SUMMARY

An example embodiment of the inventive concepts provides a method of improving efficiency in a process of fabricating a semiconductor device.

An example embodiment of the inventive concepts provides a method of improving productivity in the fabrication process.

According to an example embodiment of the inventive concepts, a method of fabricating a semiconductor device includes providing a substrate including a cell region and a peripheral region, forming a cell gate structure on the cell region, forming a peripheral gate structure on the peripheral region, forming a bit line structure on the cell region, forming a preliminary conductive layer to cover the bit line structure and the peripheral gate structure, and etching the preliminary conductive layer to form a landing pad and peripheral conductive pads. The etching of the preliminary conductive layer includes forming a lower layer and a photoresist layer on the preliminary conductive layer, performing a first exposure process on the photoresist layer, performing a second exposure process on the photoresist layer, and etching the preliminary conductive layer using the photoresist layer and the lower layer as an etch mask. The first exposure process exposes a portion of the photoresist layer that is on the cell region to light.

According to an example embodiment of the inventive concepts, a method of fabricating a semiconductor device includes providing a substrate including a cell region and a peripheral region, forming a cell gate structure on the cell region, forming a peripheral gate structure on the peripheral region, forming bit line structures on the cell region, forming node contacts and insulating fences, the node contact being interposed between adjacent ones of the bit line structures, the insulating fences being interposed between the node contacts, forming a preliminary conductive layer to cover the bit line structure, the node contacts, the insulating fences, and the peripheral gate structure, and etching the preliminary conductive layer to form a landing pad and peripheral conductive pads. The etching of the preliminary conductive layer includes forming a lower layer and a photoresist layer on the preliminary conductive layer, performing a first exposure process on the photoresist layer, performing a second exposure process on the photoresist layer, and etching the preliminary conductive layer using the photoresist layer and the lower layer as an etch mask. The first exposure process is a DUV lithography process, and the second exposure process is an EUV lithography process.

According to an example embodiment of the inventive concepts, a method of fabricating a semiconductor device includes providing a substrate including a cell region and a peripheral region, forming a cell gate structure on the cell region, forming a peripheral gate structure on the peripheral region, forming a bit line structure on the cell region, forming a preliminary conductive layer to cover the bit line structure and the peripheral gate structure, and etching the preliminary conductive layer to form a landing pad and a peripheral conductive pad. The etching of the preliminary conductive layer includes forming a lower layer and a photoresist layer on the preliminary conductive layer, selectively performing a first exposure process on the photoresist layer in the cell region, not in the peripheral region, performing a second exposure process on the photoresist layer in the cell and peripheral regions, performing a developing process on the photoresist layer to form a cell resist pattern and a peripheral resist pattern, and etching the preliminary conductive layer using lower layer patterns as an etch mask, the lower patterns corresponding to the cell and peripheral resist patterns, respectively. A smallest size of the cell resist pattern is smaller than a smallest size of the peripheral resist pattern.

### BRIEF DESCRIPTION OF THE DRAWINGS

FIG. 1 is a plan view illustrating a semiconductor device according to an example embodiment of the inventive concepts.

FIG. 2 is an enlarged plan view illustrating a portion ‘M’ of FIG. 1.

FIG. 3A is a sectional view taken along a line A-A′ of FIG. 2.

FIG. 3B is a sectional view taken along a line B-B′ of FIG. 2.

FIG. 4 is a flow chart illustrating detailed steps in a process of fabricating a semiconductor device according to an example embodiment of the inventive concepts.

FIGS. 5A, 5B, 6A, 6B, 7A, 7B, 8A, 8B, 9A, 9B, 10A, 10B, 11A, and 11B are sectional views illustrating a method of fabricating a semiconductor device according to an example embodiment of the inventive concepts.

FIG. 12 is a sectional view provided for comparative and illustrative purposes, illustrating a method of fabricating the semiconductor device of FIG. 4.

### DETAILED DESCRIPTION

Expressions such as “at least one of,” when preceding a list of elements, modify the entire list of elements and do not modify the individual elements of the list. For example, an expression such as “at least one of A, B, and C” or “at least one selected from the group consisting of A, B, and C” may be interpreted as only A, only B, only C, or any combination of two or more of A, B, and C, such as A, B, and C, A and B, B and C, and A and C.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

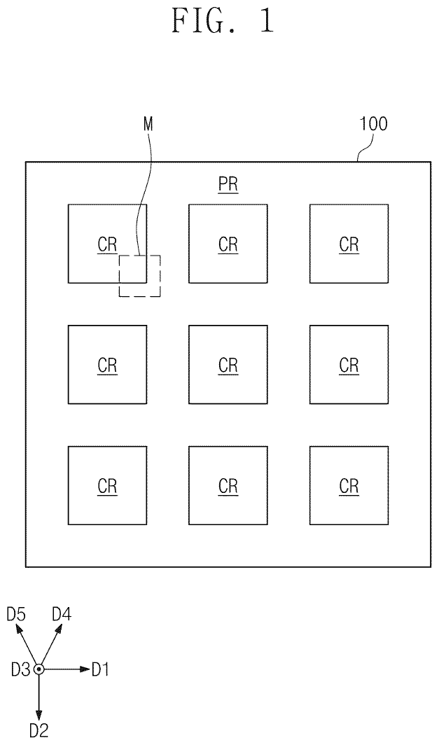

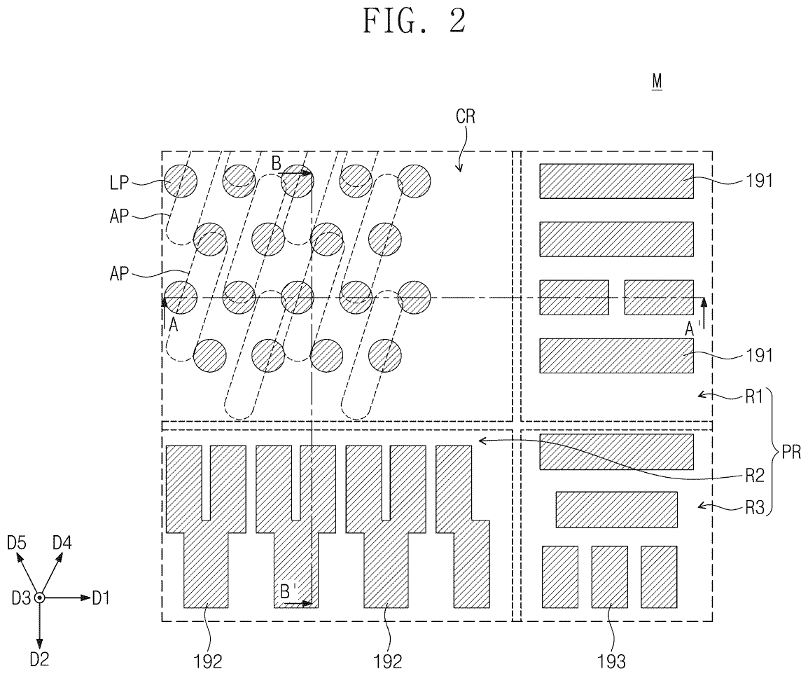

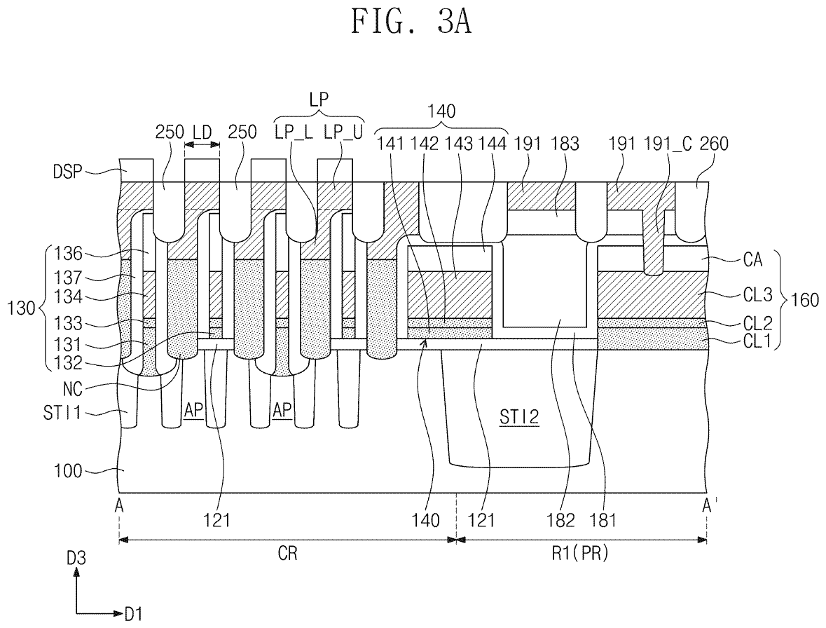

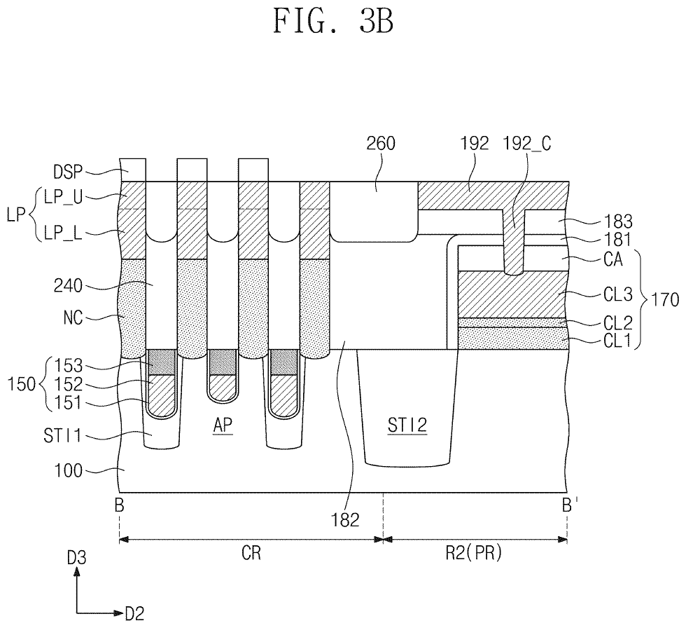

FIG. 1 is a plan view illustrating a semiconductor device according to an example embodiment of the inventive concepts. FIG. 2 is an enlarged plan view illustrating a portion ‘M’ of FIG. 1. FIGS. 3A and 3B are sectional views, which are respectively taken along lines A-A′ and B-B′ of FIG. 2.

Referring to FIGS. 1, 2, 3A, and 3B, a semiconductor device may include a substrate 100. In an example embodiment, the substrate 100 may be a semiconductor substrate. As an example, the substrate 100 may be formed of or include silicon, germanium, silicon-germanium, GaP, or GaAs. In an example embodiment, the substrate 100 may be a silicon-on-insulator (SOI) substrate or a germanium-on-insulator (GOI) substrate. The substrate 100 may have a shape of a plate, which is extended in a first direction D1 and a second direction D2. The first and second directions D1 and D2 may not be parallel to each other. In an example embodiment, the first and second directions D1 and D2 may be two different horizontal directions, which are orthogonal to each other.

The substrate 100 may include cell regions CR and a peripheral region PR, which is provided to enclose the cell regions CR. The peripheral region PR may include first regions R1, second regions R2, and third regions R3. The first region R1 may be disposed between the cell regions CR, which are arranged in the first direction D1. The second region R2 may be disposed between the cell regions CR, which are arranged in the second direction D2. The third region R3 may be disposed between adjacent ones of the first regions R1 and between adjacent ones of the second regions R2.

The cell region CR of the substrate 100 may include active patterns AP. Upper portions of the cell region CR of the substrate 100 that are extended in a third direction D3 may be defined as the active patterns AP. The third direction D3 may be non-parallel to the first and second directions D1 and D2. As an example, the third direction D3 may be a vertical direction that is orthogonal to the first and second directions D1 and D2. The active patterns AP may be spaced apart from each other.

A first device isolation layer STI1 may be provided to define the active patterns AP. The first device isolation layer STI1 may be provided in the cell region CR of the substrate 100. Each of the active patterns AP may be enclosed by the first device isolation layer STI1.

A second device isolation layer STI2 may be provided in the substrate 100. The second device isolation layer STI2 may be provided between the cell region CR and the peripheral region PR. In an example embodiment, the first and second device isolation layers STI1 and STI2 may be connected to each other to form a single object, in which any interface is not formed.

The first and second device isolation layers STI1 and STI2 may include an insulating material. As an example, the first and second device isolation layers STI1 and STI2 may be formed of or include at least one of oxide materials or nitride materials.

Cell gate structures 150 may be provided to extend in the first direction D1. The cell gate structures 150 may be arranged to be spaced apart from each other in the second direction D2. The cell gate structure 150 may be provided on the cell region CR of the substrate 100. The cell gate structure 150 may be provided on the first device isolation layer STI1 and the active patterns AP. The cell gate structure 150 may be a buried gate structure, which is buried in the active patterns AP and the first device isolation layer STI1. The active patterns AP may include impurity regions. A cell transistor may be defined by the cell gate structure 150 and the active pattern AP.

The cell gate structure 150 may include agate insulating layer 151 on the active pattern AP, a gate electrode 152 on the gate insulating layer 151, and a gate capping layer 153 on the gate electrode 152. The gate insulating layer 151 and the gate capping layer 153 may be formed of or include at least one of insulating materials. As an example, the gate insulating layer 151 may be formed of or include an oxide material, and the gate capping layer 153 may be formed of or include a nitride material. The gate electrode 152 may include a conductive material. In an example embodiment, the conductive material may be formed of or include poly silicon.

The active pattern AP may include one first portion and two second portions. The first portion of the active pattern AP may be disposed between the two second portions of the active pattern AP. The cell gate structure 150 may be provided between the first portion and a corresponding one of the second portions of the active pattern AP. The first and second portions of the active pattern AP may be spaced apart from each other by the cell gate structure 150.

Insulating patterns 121 may be provided on the cell gate structure 150, the first device isolation layer STI1, and the second device isolation layer STI2. The insulating pattern 121 may include an insulating material. In another example embodiment, the insulating pattern 121 may include a plurality of insulating layers.

Bit line structures 130 may extend in the second direction D2. The bit line structures 130 may be arranged to be spaced apart from each other in the first direction D1. The bit line structure 130 may be provided on the cell region CR of the substrate 100. The bit line structure 130 may be provided on the insulating pattern 121 and the active pattern AP. The bit line structure 130 may be electrically connected to the active pattern AP.

Each of the bit line structures 130 may include a bit line contact 131, a first conductive layer 132, a second conductive layer 133, a third conductive layer 134, a bit line capping layer 136, and a bit line spacer 137.

The bit line contacts 131 of the bit line structure 130 may be spaced apart from each other in the second direction D2. The first conductive layers 132 of the bit line structure 130 may be spaced apart from each other in the second direction D2. The bit line contacts 131 and the first conductive layers 132 of the bit line structure 130 may be alternately disposed in the second direction D2. The bit line contact 131 may be disposed on the first portion of the active pattern AP. The bit line contact 131 may penetrate the insulating pattern 121. The first conductive layer 132 may be provided on the insulating pattern 121.

The bit line contact 131 and the first conductive layer 132 may be formed of or include at least one of conductive materials. In an example embodiment, the bit line contact 131 and the first conductive layer 132 may be formed of or include poly silicon. In another example embodiment, the bit line contacts 131 and the first conductive layers 132, which are included in each bit line structure 130, may be connected to each other to form a single object, in which any interface is not formed.

The second conductive layer 133 may be provided on the bit line contacts 131 and the first conductive layers 132. The third conductive layer 134 may be provided on the second conductive layer 133. The bit line capping layer 136 may be provided on the third conductive layer 134. The second conductive layer 133 and the third conductive layer 134 may be formed of or include at least one of conductive materials. In an example embodiment, the second conductive layer 133 may be formed of or include poly silicon, and the third conductive layer 134 may be formed of or include a metallic material. The bit line capping layer 136 may include an insulating material. In another example embodiment, the number of the conductive layers, which are included in each bit line structure 130, may be greater or less than the number in the illustrated example.

The bit line spacer 137 may cover top and side surfaces of the bit line capping layer 136, side surfaces of the first to third conductive layers 132, 133, and 134, and side surfaces of the bit line contacts 131. The bit line spacer 137 may include an insulating material. In another example embodiment, the bit line spacer 137 may include a plurality of insulating layers.

Node contacts NC may be provided. The node contact NC may be provided on the cell region CR of the substrate 100. The node contact NC may be provided on the second portion of the active pattern AP. The node contact NC may be interposed between the bit line structures 130, which are adjacent to each other. The node contact NC may be provided on a side surface of the bit line structure 130. The node contact NC may include a conductive material. As an example, the node contact NC may be formed of or include poly silicon. As another example, the node contact NC may be formed of or include at least one of metallic materials (e.g., Ti, Mo, W, Cu, Al, Ta, Ru, and Ir).

Landing pads LP may be provided. The landing pad LP may be provided on the node contact NC. The landing pad LP may include a conductive material. As an example, the landing pad LP may be formed of or include a metallic material. In an example embodiment, the landing pad LP may be formed of or include at least one of metallic materials (e.g., Ti, Mo, W, Cu, Al, Ta, Ru, and Ir). In another example embodiment, a metal silicide layer may be provided between the node contact NC and the landing pad LP. In still other example embodiment, a barrier layer may be provided between the node contact NC and the landing pad LP.

The landing pad LP may include an upper portion LP_U and a lower portion LP_L. The upper portion LP_U may be a portion of the landing pad LP located at a level higher than the bit line structure 130. In another example embodiment, the upper and lower portions LP_U and LP_L of the landing pad LP may be located at a level higher than the bit line structure 130. The lower portion LP_L may be a portion of the landing pad LP connected to the node contact NC. The upper portion LP_U of the landing pad LP may be provided on the lower portion LP_L of the landing pad LP.

A portion of the upper portion LP_U of the landing pad LP may overlap a portion of the node contact NC in the third direction D3. As an example, the portion of the upper portion LP_U of the landing pad LP may vertically overlap the corresponding node contact NC, and another portion may not vertically overlap the corresponding node contact NC. In other words, the upper portion LP_U of the landing pad LP may be shifted from the corresponding node contact NC in the first direction D1 or an opposite direction thereof.

Referring back to FIG. 3A, the upper portion LP_U of the landing pad LP may have a first width LD in the first direction D1. The first width LD may be defined as a pattern size (e.g., a length in the first direction D1) of the upper portion LP_U of the landing pad LP. The pattern size may be a desired critical dimension (CD) value of a pattern to be formed by a fabrication method, which will be described below.

Insulating fences 240 may be provided. The insulating fence 240 may be provided on the gate capping layer 153 of the cell gate structure 150. The insulating fence 240 may be provided between the node contacts NC, which are adjacent to each other in the second direction D2. The insulating fence 240 may be provided between the bit line structures 130, which are adjacent to each other in the first direction D1. The insulating fence 240 may include an insulating material.

A first separation structure 250 may be provided on the insulating fence 240. The first separation structure 250 may separate the landing pads LP from each other. The first separation structure 250 may enclose the landing pad LP. The first separation structure 250 may include an insulating material.

Data storage patterns DSP may be provided. The data storage pattern DSP may be electrically connected to the active pattern AP through the landing pad LP and the node contact NC. In an example embodiment, each of the data storage patterns DSP may be a capacitor including a bottom electrode, a dielectric layer, and a top electrode. In this case, the semiconductor device including the data storage patterns DSP may be a dynamic random access memory (DRAM) device.

In another example embodiment, each of the data storage patterns DSP may include a magnetic tunnel junction pattern. In this case, the semiconductor device including the data storage patterns DSP may be a magnetic random access memory (MRAM) device. In still other example embodiment, the data storage patterns DSP may be formed of or include a phase-change material or a variable resistance material. In this case, the semiconductor device including the data storage patterns DSP may be a phase-change random access memory (PRAM) device or a resistive random access memory (ReRAM) device. In an example embodiment, each of the data storage patterns DSP may include various structures and/or materials which can be used to store data.

A dummy line structure 140 may be provided. The dummy line structure 140 may be extended in the second direction D2. The dummy line structure 140 may be disposed between the bit line structure 130 and the first region R1. The dummy line structure 140 may be disposed adjacent to the first region R1.

The dummy line structure 140 may include a first dummy conductive layer 141 on the insulating pattern 121, a second dummy conductive layer 142 on the first dummy conductive layer 141, a third dummy conductive layer 143 on the second dummy conductive layer 142, and a dummy capping layer 144 on the third dummy conductive layer 143. The first to third dummy conductive layers 141, 142, and 143 may be formed of or include at least one of conductive materials. In an example embodiment, the first and second dummy conductive layers 141 and 142 may be formed of or include poly silicon, and the third dummy conductive layer 143 may be formed of or include a metallic material. The dummy capping layer 144 may include an insulating material.

First peripheral gate structures 160 may be provided. The first peripheral gate structure 160 may be provided on the first region R1 of the substrate 100. In an example embodiment, the first peripheral gate structure 160 may be a gate of a transistor constituting a sub-word-line driver.

Second peripheral gate structures 170 may be provided. The second peripheral gate structure 170 may be provided on the second region R2 of the substrate 100. In an example embodiment, the second peripheral gate structure 170 may be a gate of a transistor constituting a sense amplifier.

Each of the first and second peripheral gate structures 160 and 170 may include a first peripheral conductive layer CL1, a second peripheral conductive layer CL2 on the first peripheral conductive layer CL1, a third peripheral conductive layer CL3 on the second peripheral conductive layer CL2, and a peripheral capping layer CA on the third peripheral conductive layer CL3. The first to third peripheral conductive layers CL1, CL2, and CL3 may be formed of or include at least one of conductive materials. In an example embodiment, the first and second peripheral conductive layers CL1 and CL2 may be formed of or include poly silicon, and the third peripheral conductive layer CL3 may be formed of or include a metallic material. The peripheral capping layer CA may include an insulating material.

A peripheral spacer 181 may cover the dummy line structure 140, the first peripheral gate structure 160, and the second peripheral gate structure 170. For example, the peripheral spacer 181 may cover top and side surfaces of the dummy line structure 140 and may be extended to a region on the insulating pattern 121. The peripheral spacer 181 may be extended to the region on the insulating pattern 121 to cover top and side surfaces of the first peripheral gate structure 160. The peripheral spacer 181 may include an insulating material.

A first filling insulating layer 182 may be provided on the peripheral spacer 181. The first filling insulating layer 182 may include a portion provided between the dummy line structure 140 and the first peripheral gate structure 160, and a portion provided between the node contact NC and the second peripheral gate structure 170. The first filling insulating layer 182 may include an insulating material.

A second filling insulating layer 183 may be provided on the first filling insulating layer 182 and the peripheral spacer 181. The second filling insulating layer 183 may include an insulating material.

First peripheral conductive pads 191, second peripheral conductive pads 192, and third peripheral conductive pads 193 may be provided on the second filling insulating layer 183. The first peripheral conductive pads 191 may overlap the first region R1 of the substrate 100 in the third direction D3. The second peripheral conductive pads 192 may overlap the second region R2 of the substrate 100 in the third direction D3. The third peripheral conductive pads 193 may overlap the third region R3 of the substrate 100 in the third direction D3. The first to third peripheral conductive pads 191, 192, and 193 may be formed of or include at least one of conductive materials.

At least one of the first peripheral conductive pads 191 may include a first contact 191_C and may be electrically connected to the first peripheral gate structure 160 through the first contact 191_C. In an example embodiment, at least one of the first peripheral conductive pads 191 may be electrically connected to a source or drain of the transistor constituting the sub-word-line driver.

At least one of the second peripheral conductive pads 192 may include a second contact 192_C and may be electrically connected to the second peripheral gate structure 170 through the second contact 192_C. In an example embodiment, at least one of the second peripheral conductive pads 192 may be electrically connected to a source or drain of the transistor constituting the sense amplifier.

In an example embodiment, at least one of the third peripheral conductive pads 193 may be electrically connected to a transistor provided on the third region R3 of the substrate 100.

A second separation structure 260 may be provided on the peripheral spacer 181, the first filling insulating layer 182, and the second filling insulating layer 183. The second separation structure 260 may separate the first peripheral conductive pads 191 from each other. The second separation structure 260 may separate the second peripheral conductive pads 192 from each other. The second separation structure 260 may separate the third peripheral conductive pads 193 from each other. A portion of the second separation structure 260 may be provided between the first peripheral conductive pad 191 and the landing pad LP. A portion of the second separation structure 260 may be provided between the second peripheral conductive pad 192 and the landing pad LP. The second separation structure 260 may include an insulating material. In another example embodiment, the first and second separation structures 250 and 260 may be connected to each other to form a single object, in which any interface is not formed.

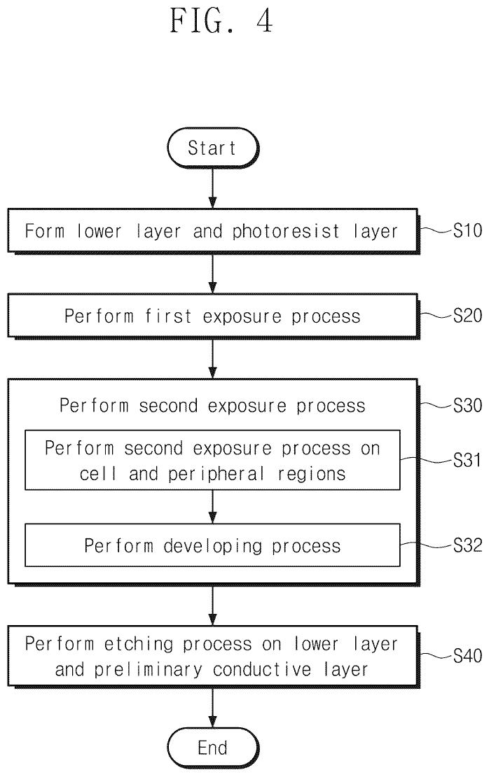

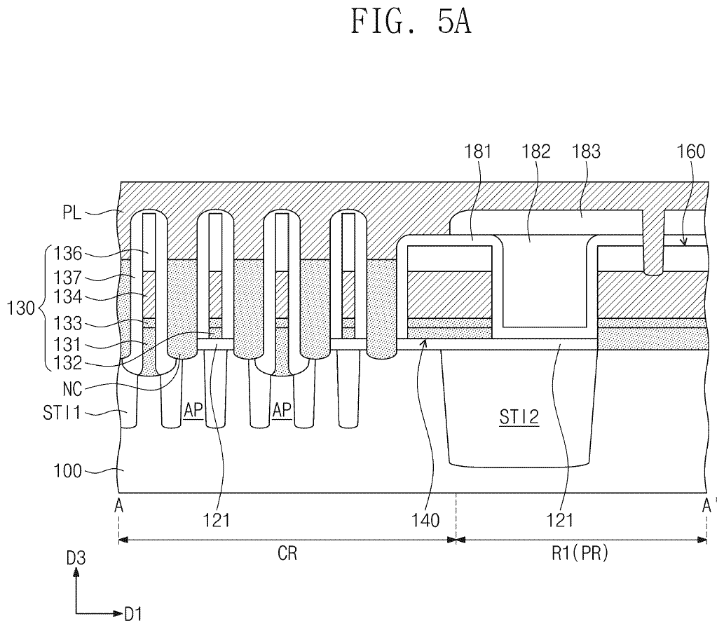

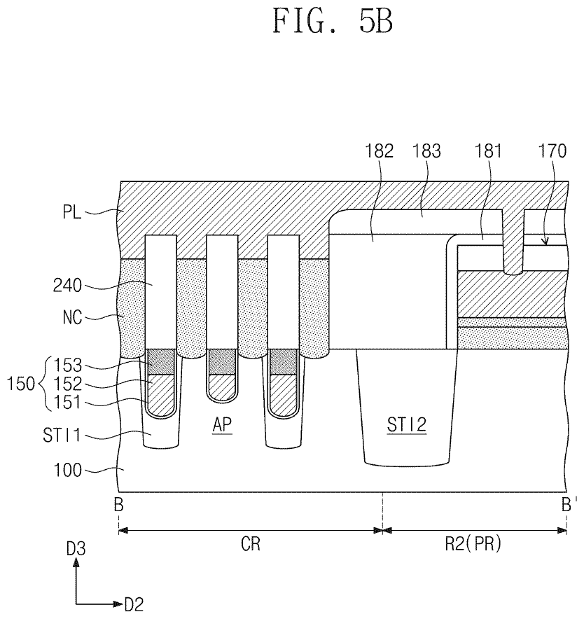

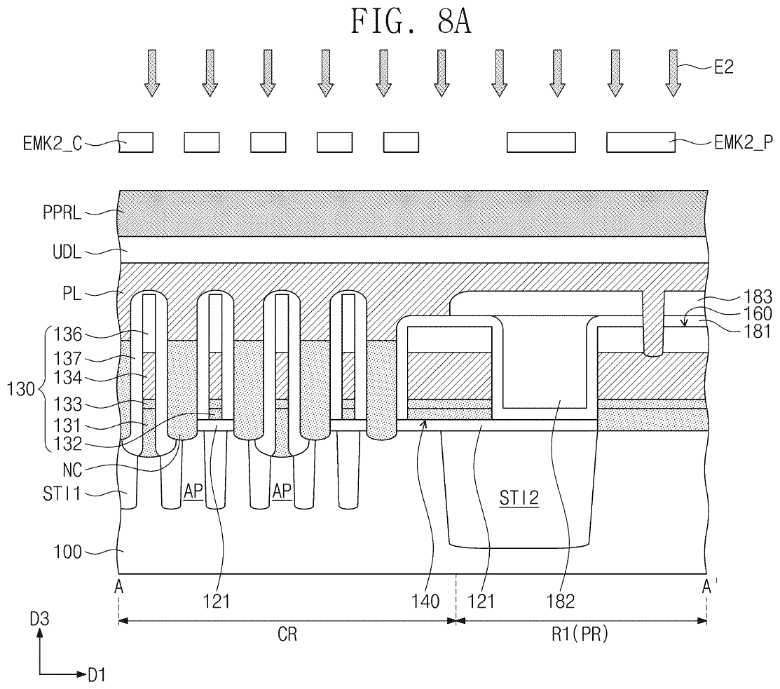

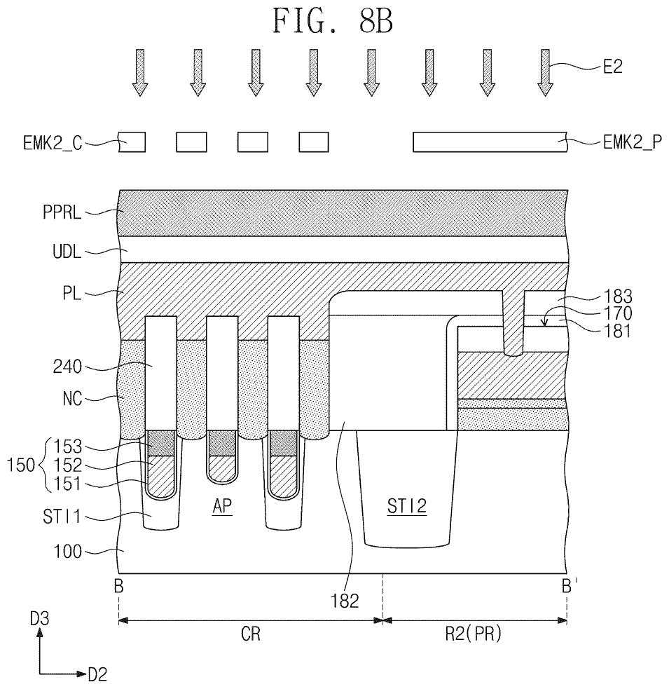

FIG. 4 is a flow chart illustrating detailed steps in a process of fabricating a semiconductor device according to an example embodiment of the inventive concept. FIGS. 5A, 6A, 7A, 8A, 9A, 10A, and 11A are sectional views taken along a line A-A′ of FIG. 2. FIGS. 5B, 6B, 7B, 8B, 9B, 10B, and 11B are sectional views taken along a line B-B′ of FIG. 2. A fabrication method according to an example embodiment will be described, based on the processes performed on the first and second regions R1 and R2 (e.g., of FIG. 2) in the cell and peripheral regions CR and PR (e.g., of FIG. 1).

Referring to FIGS. 5A and 5B, the substrate 100 including the cell region CR and the peripheral region PR may be provided. The first and second device isolation layers STI1 and STI2 may be formed on the substrate 100. The active patterns AP of the substrate 100 may be formed. The cell gate structures 150 may be formed on the cell region CR of the substrate 100. The insulating patterns 121 may be formed on the substrate 100. The bit line structure 130, the dummy line structure 140, the first peripheral gate structure 160, the second peripheral gate structure 170, the peripheral spacer 181, the first filling insulating layer 182, and the second filling insulating layer 183 may be formed. The bit line structure 130 may be formed on the cell region CR of the substrate 100. The first and second peripheral gate structures 160 and 170 may be formed on the peripheral region PR of the substrate 100.

The node contact NC may be formed to be interposed between the bit line structure 130, which are adjacent to each other, and the insulating fence 240 may be formed to be interposed between the node contacts NC, which are adjacent to each other. A preliminary conductive layer PL may be formed on the node contact NC, the insulating fence 240, the bit line structure 130, and the second filling insulating layer 183. The preliminary conductive layer PL may cover the bit line structure 130, the first peripheral gate structure 160, and the second peripheral gate structure 170. The preliminary conductive layer PL may include a conductive material. The conductive material may be impurity-containing polysilicon or a metallic material. As an example, the metal material may include at least one of Ti, Mo, W, Cu, Al, Ta, Ru, and Ir.

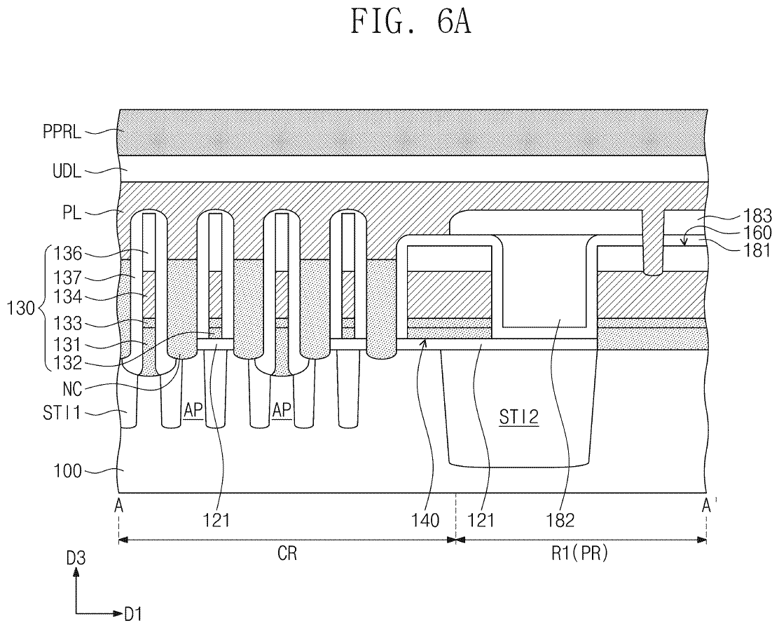

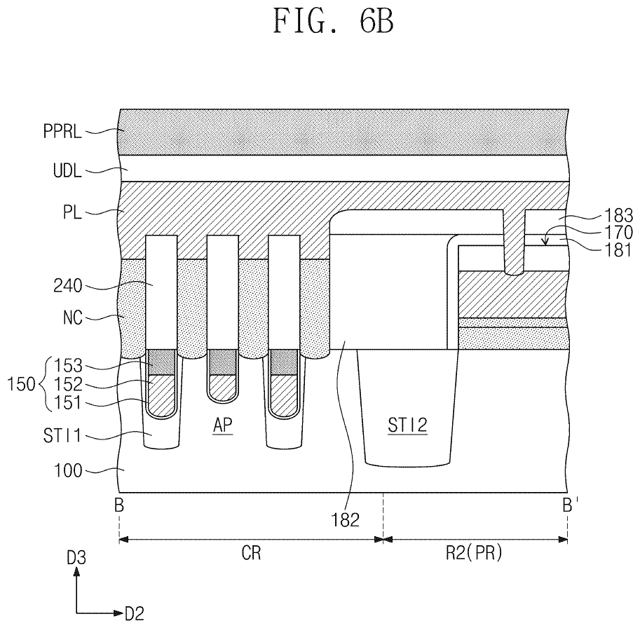

Referring to FIGS. 4, 6A, and 6B, forming a lower layer and a photoresist layer may include forming a lower layer UDL on the preliminary conductive layer PL and forming a photoresist layer PPRL on the lower layer UDL (in S10). That is, the lower layer UDL and the photoresist layer PPRL may be sequentially formed on the preliminary conductive layer PL.

The lower layer UDL may be uniformly formed on the preliminary conductive layer PL and may have a thickness ranging from 40 Å to 60 Å. The photoresist layer PPRL may be uniformly formed on the lower layer UDL and may have a thickness ranging from 280 Å to 320 Å. For example, the thickness of the lower layer UDL may be about 50 Å, and the thickness of the photoresist layer PPRL may be about 300 Å.

The lower layer UDL may be formed of or include a material having an etch selectivity with respect to the preliminary conductive layer PL. The photoresist layer PPRL may be formed of or include a material having an etch selectivity with respect to the lower layer UDL.

The lower layer UDL may be a single layer. For example, the single layer may be at least one of an amorphous carbon layer, a silicon layer, a spin-on-carbon (SOC) layer, a spin-on-hardmask (SOH) layer, a silicon nitride layer, and a silicon oxynitride layer. In an example embodiment, the lower layer UDL may include a plurality of single layers. For example, the lower layer UDL may include a first mask layer, a second mask layer, a third mask layer, and a fourth mask layer, which are sequentially stacked.

The first mask layer may, for example, include an amorphous carbon layer. The second mask layer may be formed of or include silicon (Si) or silicon oxynitride (SiON). In an example embodiment, the silicon in the second mask layer may be single crystalline silicon. The second mask layer may be formed of or include a material having an etch selectivity with respect to the first mask layer. The third mask layer may be a spin-on-carbon layer or a spin-on-hardmask layer. The fourth mask layer may be a silicon nitride layer or a silicon oxynitride layer. The fourth mask layer may be formed of or include a material having an etch selectivity with respect to the third mask layer.

The photoresist layer PPRL may be an organic photoresist layer containing an organic polymer, such as polyhydroxystyrene. The organic photoresist layer may further include a photosensitive compound which can be reacted with the extreme ultraviolet (EUV) light. The organic photoresist layer may further contain a material having high EUV absorptivity (e.g., organometallic materials, iodine-containing materials, or fluorine-containing materials). As another example, the photoresist layer PPRL may be an inorganic photoresist layer containing an inorganic material (e.g., tin oxide).

The photoresist layer PPRL may include a photosensitive material. The photosensitive material may be a positive photoresist material, but in an example embodiment, it may be a negative photoresist material. The photoresist layer PPRL may include a chemical amplification resist composite material.

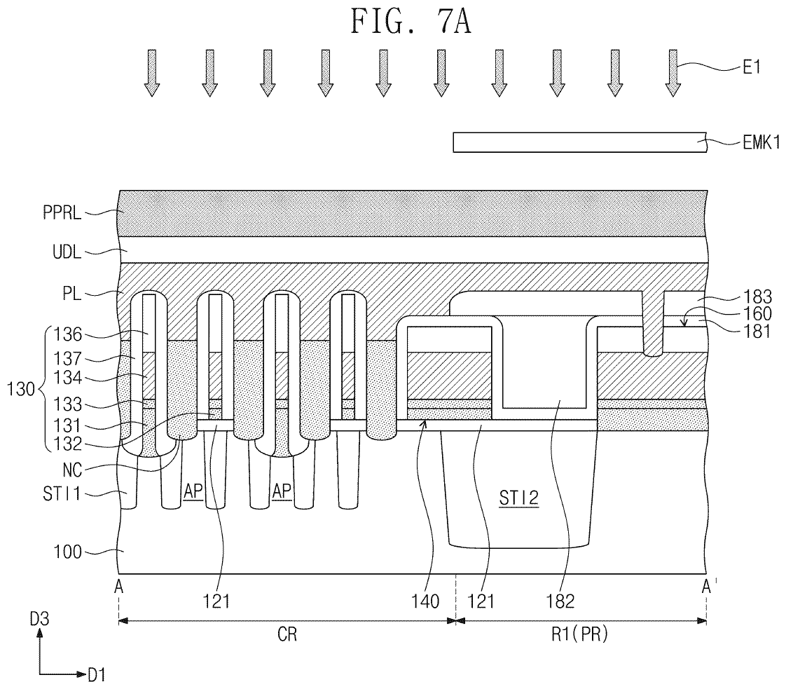

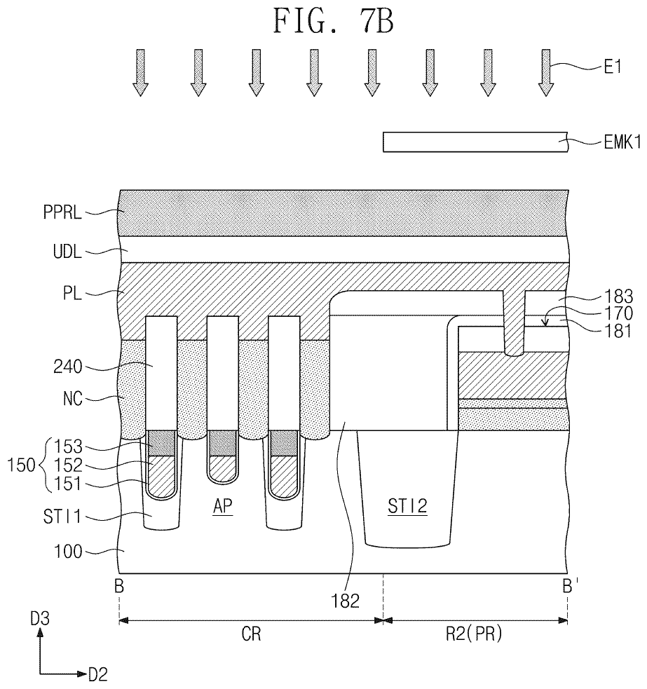

Referring to FIGS. 4, 7A, and 7B, a first exposure process (in S20) may include irradiating light on the photoresist layer PPRL in the cell region CR. That is, the first exposure process (in S20) may be selectively performed on the photoresist layer PPRL only in the cell region CR, not on the photoresist layer PPRL in the peripheral region PR. In other words, the first exposure process may expose to light a portion of the photoresist layer that is on the cell region.

For example, the first exposure process may be a deep ultraviolet light (DUV) lithography process. Light, which is used for the DUV lithography process, may have a wavelength ranging from 180 nm to 250 nm. For example, the light for the DUV lithography process may have a wavelength ranging from 192 nm to 194 nm or ranging from 247 nm to 249 nm. For example, the light for the DUV lithography process ad may have a wavelength of 193 nm or 248 nm. The light for the DUV lithography process may be defined as a first light E1, which is used for the first exposure process. That is, the first light E1 may be an ArF light having a wavelength of 193 nm or a KrF light having a wavelength of 248 nm.

The first exposure process (in S20) may include forming a first exposure mask EMK1 covering the peripheral region PR and exposing the photoresist layer PPRL on the cell region CR to the first light E1 with a first dose using the first exposure mask EMK1. The first exposure mask EMK1 may cover the photoresist layer PPRL on the peripheral region PR and expose the photoresist layer PPRL on the cell region CR.

The first light E1 may be irradiated onto the photoresist layer PPRL in an opposite direction of the third direction D3 (e.g., in a vertically downward direction). The first light E1, which is irradiated onto the peripheral region PR, may be blocked by the first exposure mask EMK1, and thus, only the exposed portion of the photoresist layer PPRL on the cell region CR may be exposed to the first light E1. The first dose of the first light E1 may be defined as a total amount of the first light E1 that is either incident into or irradiated onto a given unit area. For example, the first dose may range from 5 mJ/cm² to 7 mJ/cm².

According to the first exposure process, it may be possible to simultaneously form a cell resist pattern and a peripheral resist pattern through a second exposure process using light with a relatively small dose, as will be described below. That is, because the first exposure process is performed on only the cell region CR, the photoresist layer on the cell region CR may have an increased reactivity. Thus, the cell resist patterns on the cell region CR having a pattern density higher than that of the peripheral resist pattern on the peripheral region PR can be formed with a relatively small dose. It is called a cell-open phenomenon, and the cell-open phenomenon may be induced by the first exposure process. Because an exposure process with a low dose is performed, it may be possible to reduce a process cost in forming the landing pad on the cell region CR and the peripheral conductive pads on the peripheral region PR. That is, a process of fabricating a semiconductor device may be performed with improved efficiency.

Referring to FIGS. 4, 8A, 8B, 9A, and 9B, a second exposure process (in S30) may be performed to expose the photoresist layer PPRL in the cell and peripheral regions CR and PR to light, and in an example embodiment, the second exposure process may be performed when any developing process after the first exposure process has not been performed. In other words, the second exposure process may be performed after the first exposure process, without performing any developing process between the first exposure process and the second exposure process. Because any develop process is not performed between the first and second exposure processes, the photoresist layer PPRL may not be patterned. That is, the photoresist layer PPRL may be maintained in the form of a layer, not a pattern. For example, the second exposure process (in S30) may include performing the second exposure process on the photoresist layer PPRL in the cell and peripheral regions CR and PR (in S31) and performing a developing process on the photoresist layer PPRL (in S32).

For example, the second exposure process may be an EUV lithography process. The light, which is used for the EUV lithography process, may have a wavelength ranging from 10 nm to 124 nm. The light for EUV lithography process may have a wavelength ranging from 13.0 nm to 13.9 nm or ranging from 13.4 nm to 13.6 nm. In an example embodiment, the extreme ultraviolet may have an energy from 6.21 eV to 124 eV or from 90 eV to 95 eV. The light for the EUV lithography process may be defined as a second light E2, which is used for the second exposure process. That is, the second light E2 may have a wavelength of 13.5 nm.

The second exposure process (in S31), which is performed on the photoresist layer PPRL in the cell and peripheral regions CR and PR, may include forming a second exposure mask to cover a portion of the cell region CR and a portion of the peripheral region PR and exposing the photoresist layer PPRL to the second light E2 with a second dose using the second exposure mask.

The second exposure mask may include a second cell exposure mask EMK2_C covering a portion of the cell region CR and a second peripheral exposure mask EMK2_P covering a portion of the peripheral region PR. The second cell exposure mask EMK2_C may expose a portion of the photoresist layer PPRL on the cell region CR, and the second peripheral exposure mask EMK2_P may expose a portion of the photoresist layer PPRL on the peripheral region PR.

The second light E2 may be irradiated onto the photoresist layer PPRL in an opposite direction of the third direction D3 (e.g., in a vertically downward direction). The second light E2 may be irradiated onto an exposed portion of the photoresist layer PPRL, which is not covered with the second exposure mask. The second dose of the second light E2 may be defined as a total amount of the second light E2 that is either incident into or irradiated onto a given unit area. For example, the second dose may range from 141 mJ/cm² to 145 mJ/cm². The second dose may be greater than the first dose.

In the developing process on the photoresist layer (in S32), the developing process may be performed on the photoresist layer PPRL in the cell and peripheral regions CR and PR to form a cell resist pattern CPRP and peripheral resist patterns PPRP1 and PPRP2. In an example embodiment, a curing process may be performed on the photoresist layer PPRL, before the developing process. For example, the curing process may be a post expose bake (PEB) process, which includes a baking process that enables chemical amplification of ingredients in the photoresist layer PPRL.

In the developing process, a developer may be provided onto the photoresist layer PPRL and then a rinse step may be performed. According to the first and second exposure processes, portions of the photoresist layer PPRL may have increased solubility, and such portions may be removed together with the developer. In an example embodiment, the developer may contain tetra methyl ammonium hydroxide (TMAH) or n-butyl acetate (nBA). Other portions of the photoresist layer PPRL, which are not removed by the developer, may be used as the cell resist pattern CPRP and the peripheral resist patterns PPRP1 and PPRP2.

The cell resist pattern CPRP may be photoresist patterns, which are arranged on the lower layer UDL and in the cell region CR. A first peripheral resist pattern PPRP1 may be a photoresist pattern, which is disposed on the lower layer UDL and in the first region R1 of the peripheral region PR. A second peripheral resist pattern PPRP2 may be a photoresist pattern, which is disposed on the lower layer UDL and in the second region R2 of the peripheral region PR.

The cell resist pattern CPRP may have the smallest size. The smallest size may be defined as a width, in the first or second direction D1 or D2, of a pattern, which is formed by a patterning process to be described below. Referring back to FIG. 3A, the smallest size of the cell resist pattern CPRP may correspond to the first width LD of the upper portion LP_U of the landing pad LP in the first direction D1. The smallest size of the cell resist pattern CPRP (e.g., a CD value of the cell region CR) may correspond to the first width LD of the landing pad LP. The smallest size of the cell resist pattern CPRP may be smaller than the smallest size of each of the peripheral resist patterns PPRP1 and PPRP2, which will be described below.

Each of the peripheral resist patterns PPRP1 and PPRP2 may have the smallest size. The smallest size may be defined as a width, in the first or second direction D1 or D2, of a pattern, which is formed by a patterning process to be described below. Referring back to FIG. 2, the smallest size of each of the peripheral resist patterns PPRP1 and PPRP2 may correspond to a width of the first peripheral conductive pad 191 in the first direction D1 and a width of the second peripheral conductive pad 192 in the second direction D2. The smallest size of each of the peripheral resist patterns PPRP1 and PPRP2 (e.g., a critical dimension (CD) value of the peripheral region PR) may correspond to the width of a corresponding one of the first and second peripheral conductive pads 191 and 192.

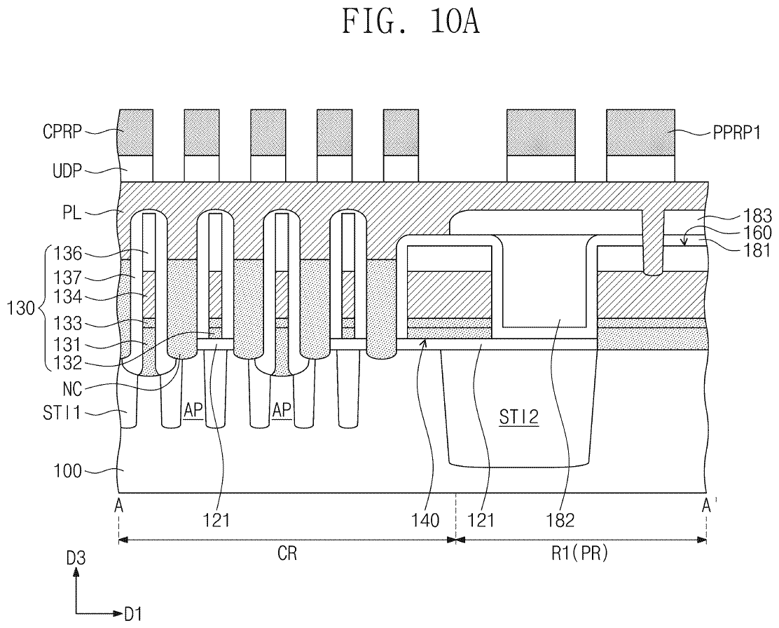

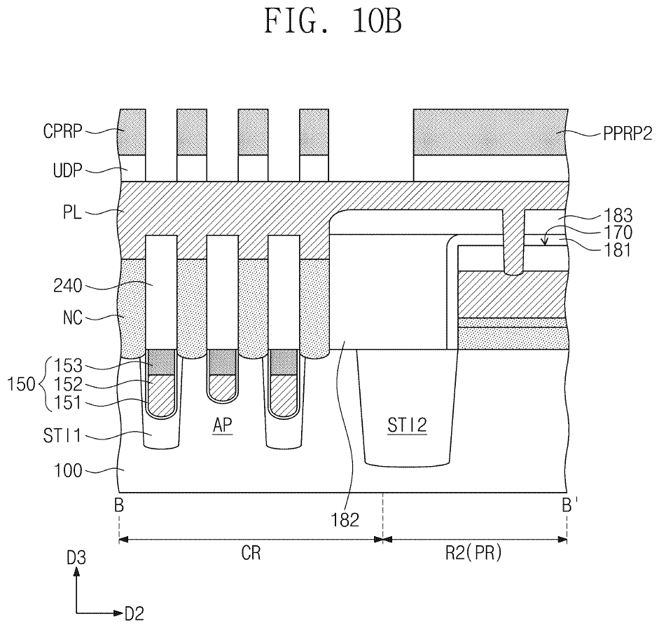

Referring to FIGS. 4, 10A, and 10B, an etching process may be performed on the lower layer and the preliminary conductive layer (in S40), and in an example embodiment, the etching process may include etching the lower layer using the photoresist layer as an etch mask and etching the preliminary conductive layer using the etched lower layer as an etch mask.

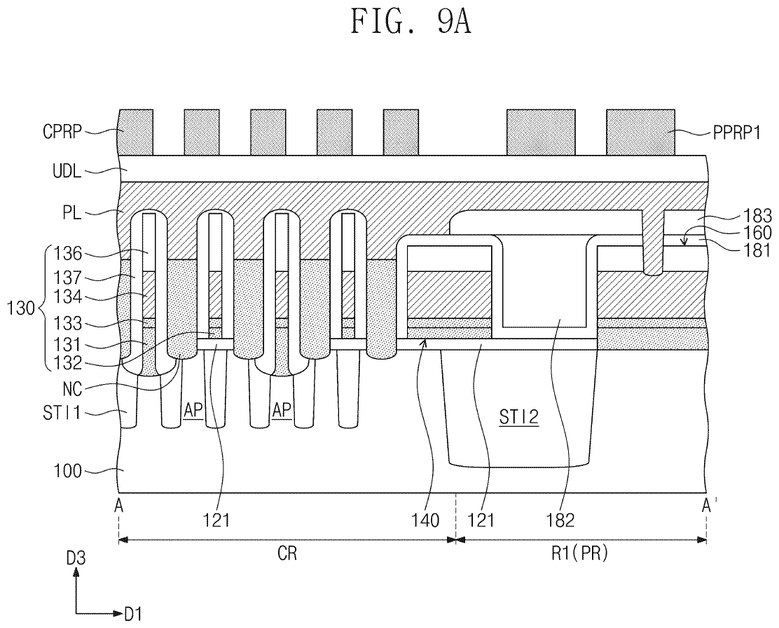

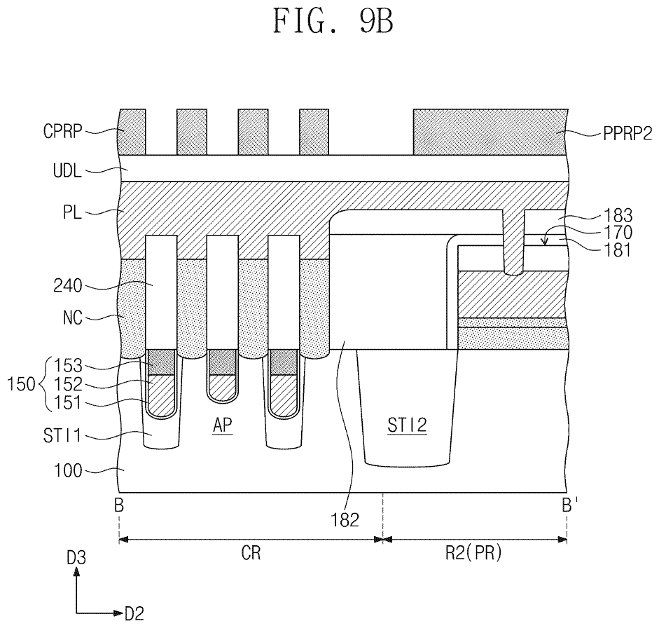

For example, the etching of the lower layer using the photoresist layer as the etch mask may be performed to etch the lower layer UDL (e.g., of FIG. 9A) using the cell resist pattern CPRP and the peripheral resist patterns PPRP1 and PPRP2 as an etch mask. This process may be performed through a dry etching process or a wet etching process. The lower layer UDL (e.g., of FIG. 9A) may be etched to form a lower layer pattern UDP. The lower layer pattern UDP may include patterns corresponding to the cell resist pattern CPRP and the peripheral resist patterns PPRP1 and PPRP2. Because the lower layer UDL (e.g., of FIG. 9A) includes a material having an etch selectivity with respect to the preliminary conductive layer PL, the preliminary conductive layer PL may not be removed.

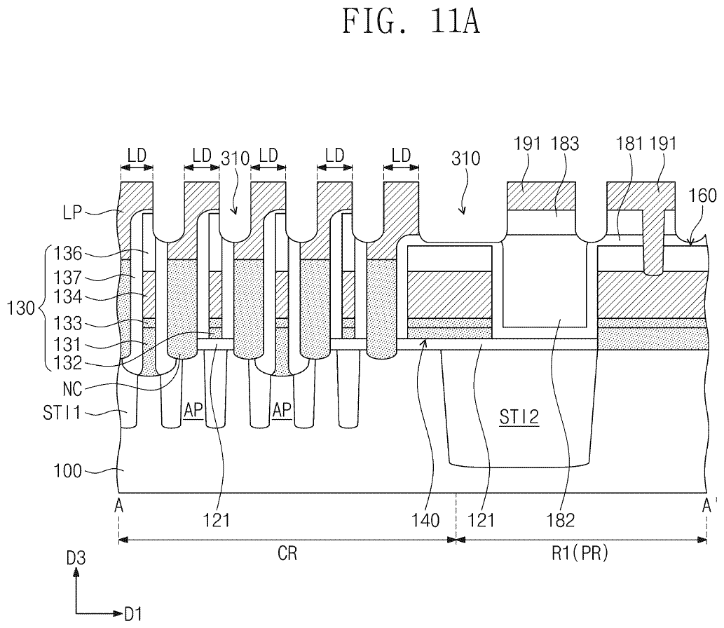

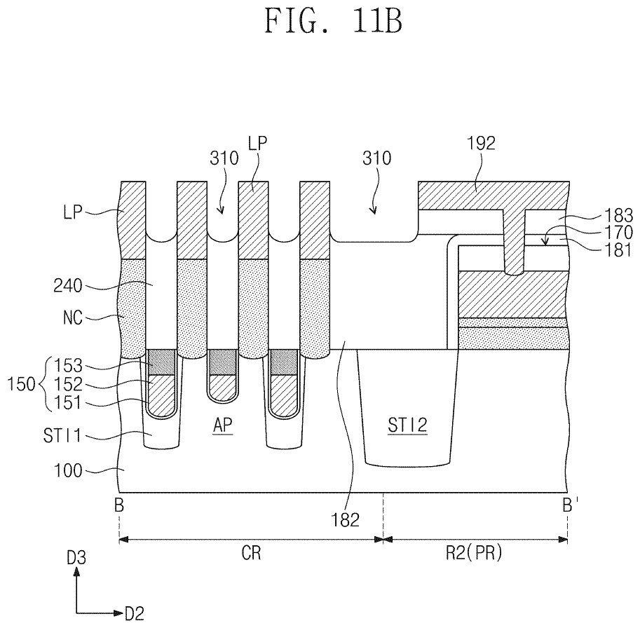

Referring to FIGS. 4, 11A, and 11B, the etching of the preliminary conductive layer PL using the etched lower layer as the etch mask may be performed to etch the preliminary conductive layer PL using the lower layer pattern UDP as an etch mask. In an example embodiment, the cell resist pattern CPRP and the peripheral resist patterns PPRP1 and PPRP2 may be removed, before the etching of the preliminary conductive layer PL. The cell resist pattern CPRP and the peripheral resist patterns PPRP1 and PPRP2 may be removed by an ashing process or a strip process.

Referring back to FIG. 2, the preliminary conductive layer PL may be etched to form the landing pads LP, the first peripheral conductive pads 191, the second peripheral conductive pads 192, and the third peripheral conductive pads 193. In other words, the preliminary conductive layer PL may be divided into the landing pads LP, the first peripheral conductive pads 191, the second peripheral conductive pads 192, and the third peripheral conductive pads 193.

The preliminary conductive layer PL may be etched to form trenches 310. The landing pads LP, the first peripheral conductive pads 191, the second peripheral conductive pads 192, and the third peripheral conductive pads 193 may be spaced apart from each other by the trenches 310.

Referring back to FIGS. 3A and 3B, the first and second separation structures 250 and 260 may be formed in the trenches 310. The data storage pattern DSP connected to the landing pad LP may be formed. The landing pad LP may have the first width LD in the first direction D1. The first width LD may be a desired critical dimension (CD) value of a pattern to be formed by the afore-described fabrication method.

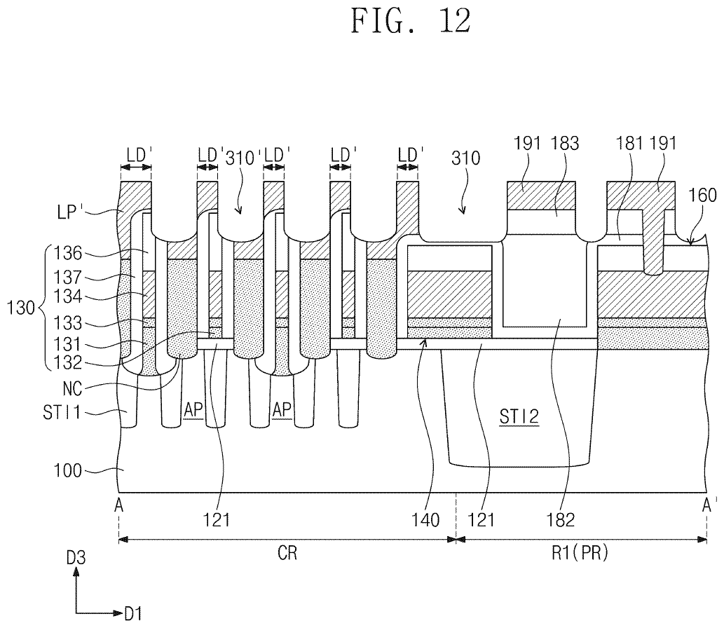

FIG. 12 is a sectional view provided for comparative and illustrative purposes, illustrating a method of fabricating the semiconductor device of FIG. 4. FIG. 12 is a sectional view taken along the line A-A′ of FIG. 2, illustrating the structure after etching the preliminary conductive layer without the first exposure process.

Referring to FIG. 12, in the case where the first exposure process is not performed, a second landing pad LP′ may be formed by etching the preliminary conductive layer, and a second trench 310′ may be formed on the cell region CR. In the fabrication method according to an example embodiment of the inventive concepts, the landing pad LP and the trench 310 on the cell region CR (e.g., of FIG. 11A) may be formed to have different sizes from each other. For example, the first width LD of the landing pad LP (e.g., of FIG. 11A) may be larger than a second width LD′ of the second landing pad LP′. Furthermore, a width of the trench 310 (e.g., of FIG. 11A) may be smaller than a width of the second trench 310′.

This is because, if the first exposure process is not performed, there is a difficulty in a cell open. In other words, the second dose in the second exposure process may be inadequate to form a landing pad with a desired CD value. Because the second width LD′ of the second landing pad LP′ decreases and the width of the second trench 310′ increases, the second landing pad LP′ may not be in contact with the node contact NC. That is, the second landing pad LP′ may not be electrically connected to the node contact NC, which increases a failure rate in the semiconductor device.

According to an embodiment of the inventive concepts, because the first exposure process and the second exposure process are successively performed, the landing pad on the cell region and the peripheral conductive pads on the peripheral region may be formed at the same time. That is, the landing pad and the peripheral conductive pads may be formed by performing the EUV lithography process, which is an expensive process, just once. Accordingly, it may be possible to reduce the total number of process steps in fabricating a semiconductor device. That is, it may be possible to improve productivity in a semiconductor fabricating method according to an example embodiment of the inventive concepts.

In a method of fabricating a semiconductor device according to an example embodiment of the inventive concepts, a first exposure process and a second exposure process may be performed on a photoresist layer on a cell region, and this may allow for the simultaneous formation of a landing pad on the cell region and peripheral conductive pads on a peripheral region. Accordingly, it may be possible to reduce the number of process steps in forming the landing pad and the peripheral conductive pads, which could consequently improve the productivity in the semiconductor fabrication process.

In a method of fabricating a semiconductor device according to an example embodiment of the inventive concepts, because the first exposure process is performed on the photoresist layer on the cell region, a dose in the second exposure process may be lowered. Thus, it may be possible to reduce a process cost for an EUV lithography process of forming the landing pad and the peripheral conductive pads and to improve the efficiency in the semiconductor fabrication process.

While some example embodiments of the inventive concepts have been particularly shown and described, it will be understood by one of ordinary skill in the art that variations in form and detail may be made therein without departing from the spirit and scope of the attached claims.

What is claimed is:

1. A method of fabricating a semiconductor device, comprising:
providing a substrate including a cell region and a peripheral region;
forming a cell gate structure on the cell region;
forming a peripheral gate structure on the peripheral region;
forming a bit line structure on the cell region;
forming a preliminary conductive layer to cover the bit line structure and the peripheral gate structure; and
etching the preliminary conductive layer to form a landing pad and peripheral conductive pads,
wherein the etching of the preliminary conductive layer comprises,
forming a lower layer and a photoresist layer on the preliminary conductive layer,
performing a first exposure process on the photoresist layer,
performing a second exposure process on the photoresist layer, and
etching the preliminary conductive layer using the photoresist layer and the lower layer as an etch mask, and
wherein the first exposure process exposes a portion of the photoresist layer that is on the cell region to light.

2. The method of claim 1, wherein
the forming of the lower layer and the photoresist layer on the preliminary conductive layer comprises sequentially forming the lower layer and the photoresist layer on the preliminary conductive layer, and
the lower layer comprises a material having an etch selectivity with respect to the preliminary conductive layer.

3. The method of claim 2, wherein the lower layer comprises a plurality of layers.

4. The method of claim 3, wherein
the plurality of layers comprises a first mask layer, a second mask layer, a third mask layer, and a fourth mask layer, which are sequentially stacked,
the first mask layer comprises an amorphous carbon layer,
the second mask layer comprises a silicon layer,
the third mask layer comprises a spin-on-carbon layer or a spin-on-hardmask layer, and
the fourth mask layer comprises a silicon nitride layer or a silicon oxynitride layer.

5. The method of claim 1, wherein the first exposure process is a deep ultraviolet light (DUV) lithography process.

6. The method of claim 5, wherein a wavelength of the light in the DUV lithography process is 193 nm or 248 nm.

7. The method of claim 1, wherein the performing of the second exposure process on the photoresist layer comprises:
performing the second exposure process on an entire top surface of the substrate; and
performing a developing process on the photoresist layer.

8. The method of claim 7, wherein the second exposure process on the photoresist layer is performed after the first exposure process, without performing any developing process between the first exposure process and the second exposure process.

9. The method of claim 7, wherein the second exposure process is an extreme ultraviolet (EUV) lithography process.

10. The method of claim 9, wherein a wavelength of the light in the EUV lithography process is 13.5 nm.

11. The method of claim 1, wherein the etching of the preliminary conductive layer using the photoresist layer and the lower layer as the etch mask further comprises:
etching the lower layer using the photoresist layer as an etch mask; and
etching the preliminary conductive layer using the etched lower layer as an etch mask.

12. A method of fabricating a semiconductor device, comprising:
providing a substrate including a cell region and a peripheral region;
forming a cell gate structure on the cell region;
forming a peripheral gate structure on the peripheral region;
forming bit line structures on the cell region;
forming node contacts and insulating fences, the node contacts being interposed between adjacent ones of the bit line structures, the insulating fences being interposed between the node contacts;
forming a preliminary conductive layer to cover the bit line structure, the node contacts, the insulating fences, and the peripheral gate structure; and
etching the preliminary conductive layer to form a landing pad and peripheral conductive pads,
wherein the etching of the preliminary conductive layer comprises,
forming a lower layer and a photoresist layer on the preliminary conductive layer,
performing a first exposure process on the photoresist layer,
performing a second exposure process on the photoresist layer, and
etching the preliminary conductive layer using the photoresist layer and the lower layer as an etch mask,
wherein the first exposure process is a DUV lithography process, and
wherein the second exposure process is an EUV lithography process.

13. The method of claim 12, wherein the performing of the first exposure process on the photoresist layer comprises:
forming a first exposure mask covering the peripheral region; and
exposing the photoresist layer on the cell region to a first light with a first dose, using the first exposure mask.

14. The method of claim 13, wherein the performing of the second exposure process on the photoresist layer comprises:
forming a second exposure mask to cover a portion of the cell region and a portion of the peripheral region;
exposing the photoresist layer to a second light with a second dose, using the second exposure mask; and
performing a developing process on the photoresist layer to form a cell resist pattern and a peripheral resist pattern.

15. The method of claim 14, wherein the photoresist layer comprises a positive photoresist material or a negative photoresist material.

16. The method of claim 14, wherein
a wavelength of the first light is 193 nm or 248 nm, and
a wavelength of the second light is 13.5 nm.

17. The method of claim 14, wherein the second dose is higher than the first dose.

18. The method of claim 14, wherein the first dose ranges from 5 mJ/cm² to 7 mJ/cm², and the second dose ranges from 141 mJ/cm² to 145 mJ/cm².

19. A method of fabricating a semiconductor device, comprising:
providing a substrate including a cell region and a peripheral region;
forming a cell gate structure on the cell region;
forming a peripheral gate structure on the peripheral region;
forming a bit line structure on the cell region;
forming a preliminary conductive layer to cover the bit line structure and the peripheral gate structure; and
etching the preliminary conductive layer to form a landing pad and a peripheral conductive pad,
wherein the etching of the preliminary conductive layer comprises,
forming a lower layer and a photoresist layer on the preliminary conductive layer,
selectively performing a first exposure process on the photoresist layer in the cell region, not in the peripheral region,
performing a second exposure process on the photoresist layer in the cell and peripheral regions,
performing a developing process on the photoresist layer to form a cell resist pattern and a peripheral resist pattern, and
etching the preliminary conductive layer using lower layer patterns as an etch mask, the lower layer patterns corresponding to the cell and peripheral resist patterns, respectively, and
wherein a smallest size of the cell resist pattern is smaller than a smallest size of the peripheral resist pattern.

20. The method of claim 19, wherein
the first exposure process is a DUV lithography process,
the second exposure process is an EUV lithography process, and
a second dose in the second exposure process is greater than a first dose of the first exposure process.
